(19) United States
(12) Patent Application Publication
(10) Pub. No.: US 2009/0268527 A1
(43) Pub. Date: Oct. 29, 2009

(54) SONOS MEMORY DEVICE AND METHOD OF OPERATING A SONOS MEMORY DEVICE

(75) Inventors: Michiel J. Van Duuren, Valkenswaard (NL); Robertus T.F. Van Schaijk, Eindhoven (NL); Nader Akil, Sterrebeek (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/301,427

(22) PCT Filed: May 16, 2007
(86) PCT No.: PCT/IB07/51873

§ 371 Date: Nov. 18, 2008

(30) Foreign Application Priority Data
May 19, 2006 (EP) 06114257.6

(51) Int. Cl. G11C 16/04; G11C 16/06

(52) U.S. Cl. 365/185.29; 365/185.18; 365/185.23

(57) ABSTRACT

The present invention relates to a memory device, hereinafter SONOS memory device, comprising SONOS memory cells having a control gate terminal connected to a SONOS layer stack with a nitride layer, a source terminal and a drain terminal; and a programming unit, which is connected to the drain terminal and to the control gate terminal and which is configured to apply a predetermined positive drain voltage to the drain terminal of the selected SONOS memory cell and a predetermined negative gate voltage to the control gate terminal of the selected SONOS memory cell each upon receiving a programming request addressed to a selected SONOS memory cell, the drain voltage and the gate voltage being suitable for creating hot holes at a drain side of the selected SONOS memory cell in a gate-assisted band-to-band-tunneling process and for injecting the hot holes into the nitride layer of the selected SONOS memory cell, thus switching the selected SONOS memory cell from a high-V_{T} state to a low-V_{T} state.

The present invention relates to a memory device comprising SONOS memory cells and to a method of operating a memory device comprising SONOS memory cells. Furthermore, the invention relates to a programming device for a memory device comprising SONOS memory cells.

Embedded one-time-programmable (OTP) memories are often used in systems-on-chip (SOC), in order to achieve a higher flexibility than with masked read-only-memory (ROM). Other than masked ROM, program code contained in OTP memories can be varied per customer, and it can be debugged without having to provide new masks after making changes to the program code. On the other hand, embedded OTP memory is less expensive than multi-time-programmable memories like flash memories.

Several OTP memory types are known. Floating-gate (FG) OTP memories comprise an isolated floating-gate layer between a semiconductor substrate and a control-gate (CG) terminal. For programming a FG memory cell, an initializing erase operation is required that brings all memory cells of the memory device into a pre-defined state before the memory can be used to store data. It is only after this block erase operation that cells can selectively be programmed, i.e., that the information content of selected memory cells is changed in order to store data.

In general, the erase procedure has to be performed twice for OTP memories: One block erase procedure is performed before testing, and a second block erase procedure is performed after testing and before shipment of the memory device. An erase operation by UV illumination makes use of a generation of electron-hole pairs with highly energetic electrons, which can freely pass the barrier of the tunnel oxide between the floating gate and the substrate. This way, the internal electrical field between the floating gate and the substrate is reduced to zero, thus removing the charge previously stored on the floating gate. The state assumed by all FG memory cells after UV erasure is a state, in which the threshold voltage V_{T} exhibits a low value. As is well known in the field of semiconductor memory technology, the threshold voltage V_{T} characterizes the onset of channel conductivity in metal-oxide-semiconductor field effect (MOSFET) type transistors.

Programming of floating-gate OTP memory cells can be achieved by means of channel hot electron injection (CHEI) into the floating gate. The presence of a charged floating gate causes a shift of the threshold voltage V_{T} to higher values. By applying a read voltage having an intermediate value between the low-V_{T} and the high-V_{T} values, the charge state of the floating gate and therefore information stored in the memory cell can be detected.

The main issue of FG memory devices is their high program and erase voltage (˜15V) which is not scalable. In case of embedded memories, large high voltage (HV) transistors are needed to handle the HV and hence add to manufacturing cost and complexity.

Silicon-oxide-nitride-oxide-silicon (SONOS) memories are potential candidates for replacing floating gate memories thanks to their ease of integration which consists of processing one polysilicon layer instead of two, and moderate program and erase voltage which help reducing the HV transistor area, compared to FG.

Although the program and erase voltages in SONOS (˜10V) are significantly lower than in FG, HV transistors are still needed to generate and switch the HV and hence make the process expensive and complex.

It is an object of the present invention to provide a SONOS memory device, which can be programmed without using high-voltage transistors.

It is a further object of the invention to provide a method of operating a SONOS memory device, which allows programming the memory cells in a bit-selective manner without employing high-voltage transistors.

The invention is defined by the independent claims. The dependent claims define advantageous embodiments.

According to a first aspect of the invention a memory device is provided, which will hereinafter also be referred to as a SONOS memory device. The SONOS memory device comprises SONOS memory cells having a control gate terminal connected to a SONOS layer stack with a nitride layer, a source terminal and a drain terminal. Furthermore, the SONOS memory device of the invention comprises a programming unit, which is connected to the drain terminal and to the control gate terminal. The programming unit is configured to apply a predetermined positive voltage to the drain terminal and a predetermined negative voltage to the control gate terminal of a selected SONOS memory cell upon receiving a programming request addressed to the selected SONOS memory cell. The predetermined drain voltage and the predetermined gate voltage are suitable for creating hot holes at a drain of the selected SONOS memory cell in a band-to-band tunneling process, and suitable for injecting a fraction of the hot holes created this way into the nitride layer of the SONOS layer stack of the selected SONOS memory cell, thus switching the selected SONOS memory cell from a high-V_{T} state to a low-V_{T} state.

A SONOS memory device according to the present invention is formed by any electronic device that contains SONOS memory cells and the programming unit as defined above. In particular, the respective electronic device need not be restricted to a functionality of a memory device, but can have additional functionality according to a specific application purpose. Examples of SONOS memory devices according to the invention are systems-on chip that comprise SONOS memory cells and the programming unit as defined above. Similarly, processors, microcontrollers, and application-specific integrated circuits (ASICs), etc can form a SONOS memory device according to the present invention.

A SONOS layer stack of the SONOS memory cells contains the following layer sequence: a polysilicon layer-blocking oxide layer-a silicon nitride layer-a bottom (or tunnel) oxide layer-a silicon layer (substrate). Herein, the polysilicon layer forms a gate terminal. The blocking oxide is typically formed by a silicon oxide (SiO₂) layer, as is the bottom oxide layer. The final silicon layer is typically formed by the substrate, which contains a channel region between source and drain terminals, as typical for MOSFET type transistors. Layer thicknesses, impurity content or material variations in the SONOS layer stack are well known to a person skilled in the art, and will be further specified by preferred embodiments described further below.

In the context of the present application the following sign convention is used when referring to high and low values of the threshold voltage V_{T}: When comparing threshold voltages, the sign of the voltage shall be taken into account. Therefore, irrespective of its magnitude, a negative voltage is always lower than a positive voltage. As an example, a threshold voltage of −3 V is considered to be lower in the context of the present application than a positive threshold voltage of 0.5 V. Throughout the present application, voltage values without a sign are to be considered to be positive voltage values.

The invention is based on recognizing that known programming methods of floating-gate memory devices cannot be applied in low-voltage SONOS memory devices. SONOS devices react differently to an erase operation such as UV illumination. After UV illumination, a SONOS memory cell takes on a state of equilibrium, which is a high-V_{T} state, instead of a low-V_{T} state, which, for comparison, is assumed by floating memory cells. This difference in the behavior of SONOS memory cells over FG memory cells applies to both NMOS and PMOS memory cells, under the above sign convention. The different behavior of SONOS memory cells is currently assigned to a filling of a substantial fraction of trap sites in the nitride layer with electrons created by the UV illumination.

The present invention is based on the novel concept of employing a hot-hole injection (HHI) mechanism for programming a selected memory cell. Hot holes can be generated by means of gate-assisted band-to-band tunneling (BTBT) at the drain terminal of a selected SONOS memory cell. The gate-assisted BTBT process occurs under suitable bias conditions. For instance, a suitable negative gate voltage is applied to the gate terminal of the selected memory cell, and a suitable positive drain voltage is applied to the drain terminal of the SONOS memory cell. This way, a large electric field is created in the silicon substrate at the drain. The electric field component relevant for the BTBT process is directed parallel to the substrate surface. One of the effects of this large “horizontal” field is that holes are generated in the substrate by the BTBT process. These holes are highly energetic (“hot”) and can therefore possibly be injected into the nitride layer of the SONOS layer stack, thus crossing the barrier formed by the bottom oxide layer.

By choosing a suitable negative gate voltage and a suitable positive drain voltage, a programming of a SONOS memory cell can be performed. Programming is understood to be switching the SONOS memory cell from the high-V_{T} state assumed after an erasure to a low-V_{T} state. This switching can be interpreted as switching the SONOS memory cell from a bit value of “0” to a bit value of “1”, or vice versa, according to a given convention.

Addressing of an individual selected SONOS memory cell is thus enabled. The programming unit of the SONOS memory device of the present invention is configured to address each SONOS memory cell in a bit-selective manner by applying the predetermined positive drain voltage to the drain terminal of the selected SONOS memory cell and a predetermined negative gate voltage to the control gate terminal of the selected memory cell.

The hot-hole injection process just described is different from a so called direct tunneling process, which in the art is also referred to as a modified Fowler-Nordheim tunneling process. In this process, which is not used for programming SONOS memory cells according to the present invention, holes are transferred directly from the substrate to a conduction band state in the nitride layer or to a localized bound state at a trap site in the nitride layer. Thus, no hot holes are generated in the substrate in this direct-tunneling process.

While the concept of hot hole injection as such is known from a different specific memory device, it has not been considered a useful candidate for application in the context of SONOS memory devices. From U.S. Pat. No. 5,953,255 is known that FG memory cells in a NAND-type array can be erased by performing an UV erasure, which brings the threshold voltage to a value close to the neutral V_{T}, and programmed by hot-hole-injection, which decreases V_{T}. This implies that, in order to get a large enough V_{T} window for reliable read-out, the (HHI) programmed V_{T} should be chosen relatively far below the neutral V_{T} of the FG device, whereas the (UV) erased V_{T} is almost equal to the neutral V_{T}. This is a bad situation for data retention. However, the inventors observed that in the SONOS-based cell of the present invention the V_{T} window is much more symmetrically centered around the neutral V_{T}. Therefore, the HHI programmed V_{T} can be chosen closer below the neutral V_{T} without sacrificing the V_{T} window, which is advantageous for data retention. Therefore, there is a big advantage of using the program and erase mechanisms (HHI and UV, respectively) for SONOS instead of FG devices, which is not suggested by U.S. Pat. No. 5,953,255.

The SONOS memory device of the invention has the advantage that the programming mechanism underlying the operation of the programming unit allows using predetermined positive drain voltages and negative gate voltages, which can be provided by state-of-the-art I/O-transistors, as will be further explained in the context of a preferred embodiment further below. This way, the manufacturing process of the SONOS memory device of the invention is simplified in comparison to prior-art devices, since the processing of high-voltage transistors is omitted. As a consequence, the cost of manufacturing the SONOS memory device of the present invention is particularly low.

In the following, preferred embodiments of the SONOS memory device of the first aspect of the invention will be presented. Unless explicitly stated otherwise, it is understood that the additional features of the embodiments can be combined with each other.

In a preferred embodiment of the SONOS memory device of the invention, the programming unit is configured to apply a drain voltage between 3 V and 7 V and a gate voltage between −2 V and −6 V upon receiving the programming request addressed to the selected memory cell. These voltages have been determined as suitable for switching a SONOS memory cell from the high-V_{T} state to the low-V_{T} state in a programming step.

In a further preferred embodiment, a semiconductor substrate containing the memory cells comprises a substrate terminal. In this embodiment, the programming unit is configured to apply a substrate voltage of 0 V to the substrate terminal in combination with the above mentioned drain and gate voltage values. With the given voltage intervals, a programming of an erased memory cell can be achieved by electrical programming using a HHI mechanism within a particularly short time of approximately 1 second.

In a further preferred embodiment, the programming unit is further configured to apply a predetermined source voltage to a source terminal of the selected memory cell, where the source voltage is preferably equal to the drain voltage. This embodiment is particularly useful for SONOS memory devices which have SONOS memory cells with a relatively long channel between source and drain terminals. In this case, the generation of hot holes at both the source and the drain is more efficient. For shorter devices, however, the hole generation is more efficient, if only the drain is used for hole generation. This is also true in most array configurations, such as 1 T NOR, where only the drain terminal can be biased selectively for programming. This will be further elucidated below in the context of the description of the appended Figures.

As indicated above, the programming unit preferably comprises input/output transistors, which are connected to the SONOS memory cells and which are nominally configured to provide a maximum output voltage of approximately 2.5 V. The nominal configuration of such I/O-transistors does not exclude the switching of moderately higher output voltages for a relatively short time. Therefore, the tolerance of state-of-the-art I/O-transistors towards higher voltages can be used in the present embodiment to avoid an incorporation of dedicated high-voltage transistors for switching the voltages mentioned in the previous embodiment. The time span, during which voltage higher than the nominal maximum output voltage of the I/O-transistors has to be provided, amounts to several seconds at most. Furthermore, these voltages are typically provided only once or twice during the lifetime of the SONOS memory device.

In a further preferred embodiment, the SONOS layer stack has a bottom oxide layer adjacent to a substrate on one side and to the nitride layer on another side, and wherein the thickness of the bottom oxide layer is between 5 and 7 nm. In this embodiment, the data retention after programming a memory cell is improved. At this point, the hot hole injection mechanism used according to the present invention has a clear advantage over direct tunneling, since this mechanism does not work for SONOS memory cells with a bottom oxide layer thicker than 2.5 to 3 nanometers. Such thin tunnel oxides imply a potential data retention hazard.

In order to further reduce the predetermined positive drain voltage and the predetermined negative gate voltage that has to be applied by the programming unit of the SONOS memory device in a programming operation, the doping profile of the drain region can be enhanced. Particularly a steeper doping profile of the drain junction can reduce the bias required for achieving gate-assisted band-to-band tunneling. In a preferred embodiment, therefore, a drain junction profile of the SONOS memory cells comprises a transition region, in which the dopant concentration in cm⁻³ changes by 10⁻²-10⁻⁴ times over a distance of 20-60 nanometers with increasing distance from the substrate surface.

Halo implants with same dopant atoms or electrically equivalent to the SONOS well dopant atoms can be implanted with a tilt angle of 15 to 45 degrees around the drain and source junctions to enhance the band to band tunneling current.

Several array architectures are possible for a SONOS memory device according to the present invention. A preferred embodiment, however, comprises an array of SONOS memory cells, which are connected according to a NOR architecture. In this architecture, source terminals of the SONOS memory cells are currently connected to a common-source bond pad. As will be further explained below, the common-source bond pad is useful in an electrical erase process of another embodiment.

In order to keep the size of the SONOS memory cells small, it is preferred to provide only one transistor per memory cell, i.e. make use of a 1 T configuration. However, a 2 T configuration is also possible.

The programming unit preferably comprises a bit line driver, which is connected in parallel to the drain terminals of respective SONOS memory cells arranged along a respective bit line, and a word line driver, which is connected in parallel to the control gate terminals of respective SONOS memory cells arranged along a respective word line. The bit line driver of this embodiment is preferably configured to apply the predetermined positive voltage to the connected drain terminals of a selected bit line, and the word line driver is preferably configured to apply the predetermined negative voltage to the control gate terminals of a selected word line, each upon receiving a programming request addressed to the selected SONOS memory cell.

In this configuration, it is advantageous to provide bit line float transistors connected in series between the bit line driver and drain terminals of SONOS memory cells, which are connected to a respective bit line downstream of the bit line driver and the bit line float transistor. A gate terminal of a respective bit line float transistor is connected to a bit-line float bond pad common to all bit line float transistors. This embodiment is particularly useful for application of an electrical erase procedure instead of a UV illumination erase procedure. The advantage of an electrical erase procedure is that also packaged devices can be erased. By providing connections in the form of pins or bond pads on a packaged device, the device can even be erased several times, thus offering a cheap multi-time programming option.

In an electrical erasure procedure, a direct tunneling mechanism is preferably used, which requires application of high voltages in the range of 10 to 12 V. Since the memory transistors are in inversion (conduction) during such an electrical erasure procedure (e.g., V_{GS}≈10 V), the bias applied to the drain terminals is preferably the same bias as applied to the source terminal, in order to prevent excessive channel currents. The present embodiment uses bit line float transistors that can be switched to leave the bit lines floating during an electrical erasure procedure. Preferably, the bit line float transistors are configured to isolate and withstand approximately −7 V. Since this bias situation only occurs for a limited time of a few seconds, the bit line float transistors can be made for instance with I/O-transistors or reference transistors. During read operations, the bit line float transistors are opened to pass the voltage to the drain of the selected cell. This can be achieved by applying the power supply potential V_{DD} to the bit-line float bond pad. During write operations, a higher voltage is needed to pass the required writing voltage between 3 and 7V to the drain of the selected cell. To pass a voltage X to the drain of the selected SONOS cell, the voltage of the bit-line float bond pad should be at least higher than X+V_{T},_{F}, where V_{T,F} denotes the threshold voltage of the bit-line float transistor.

A preferred further embodiment comprises a well bond pad, which is connected to doped wells of the SONOS memory cells in the substrate. The well bond pad is useful during the electrical erasure procedure and is used for biasing the well. Typically, the same voltage is applied as to the common source bond pad and to the bit line float bond pad. The voltage can be applied by an external programming device. Preferably, protection against electrostatic discharge (ESD) is provided.

In order to enhance the isolation during the application of an erase voltage, the SONOS memory cells of one embodiment further comprise a buried isolation well of an opposite conductivity type compared to the doped well and arranged underneath the doped well.

High-voltage transistors for the erasure procedure can be avoided by distributing the bias over the gate and source terminals. The programming unit is preferably configured to apply a power supply voltage V_{DD} or a voltage of approximately 3 V to control gate terminals of the SONOS memory cells for a time span of between 0.1 and 5 seconds, upon receiving a command to erase stored information from all memory cells. The programming unit is preferably further configured to apply this gate voltage in synchronism with a source bias externally applied to the source terminal during the electrical erase procedure. As a result, a bias between gate and source of approximately 10 V can be applied, which is sufficient to trigger direct tunneling processes, which erase all memory cells within a time span of 0.1 to 5 seconds. This short time span is clearly an advantage over UV illumination erasure, which takes up to 20 minutes and can only be applied on wafer level.

The SONOS memory device can also be formed by 2 T memory cells. In this case, one memory transistor and one select transistor are included in each memory cell. A select line driver is provided and connected in parallel to excess gate terminals of select transistors of SONOS memory cells of a respective word line, and configured to drive the select transistors of the respective word line according to incoming read or write commands.

According to a second aspect of the invention, a method of operating a memory device comprising SONOS memory cells is provided. The method comprises a step of programming a selected SONOS memory cell. This programming step includes: Providing the SONOS memory device in an erased state, in which the selected SONOS memory cell is in a high-V_{T} state; and applying a predetermined positive drain voltage to a drain terminal of the selected SONOS memory cell and a predetermined negative gate voltage to a control gate terminal of the selected SONOS memory cell, the drain voltage and the gate voltage being suitable for creating hot holes at a drain side of the selected SONOS memory cell in a band-to-band-tunneling process and for injecting the hot holes into a nitride layer of the selected SONOS memory cell, thus switching from the high-V_{T} state to a low-V_{T} state.

The operating method of the invention reflects the advantages achieved with the memory device of the first aspect of the invention.

In the following, preferred embodiments of the method of the second aspect of the invention will be presented. As before, the embodiments can be combined with each other, unless explicitly stated otherwise.

In one preferred embodiment, the step of programming the selective SONOS memory cell further includes applying a predetermined positive source voltage to a source terminal of the SONOS memory cell, the source voltage being suitable for creating hot holes also on the source side of the SONOS memory cell (p. 3, last par). This embodiment is useful for operating a memory device which contains SONOS memory cells which have relatively large channel lengths.

In a preferred embodiment, which has been explained to some extent before, the step of programming the selected SONOS memory cell comprises applying a drain voltage between 3 V and 7 V and a gate voltage between −2 V and −6V. Although the voltages exceed the maximum rating of the I/O transistors of most modern CMOS processes (approximately 2.5 V), the I/O transistors can be to switch these high voltages as they have to do so only for a very limited time span of several seconds. These voltages are particularly suited for achieving a hard-hole-injection programming mechanism.

The predetermined positive drain voltage and the predetermined negative gate voltage, such as those mentioned in the context of the previous embodiment, are preferably applied for a time span of between 0.1 second and 5 seconds. This way, fast programming is achieved and simple I/O-transistors can be used for programming the memory device.

One embodiment comprises in the step of providing the SONOS memory device in an erased state a step of erasing the SONOS memory cells by exposing the SONOS cells to ultra violet electromagnetic radiation. This embodiment is useful during manufacture of the device, where the memory cells can be erased by direct exposure of the wafer or die.

However, for opening a way to multi-time programming of the SONOS memory device, a preferred method comprises electrically erasing the SONOS memory cells in the step of providing the SONOS memory device in an erased state. This is preferably performed by applying an erase voltage bias across their control gates and their source terminals, the erase voltage bias being suitable for creating electrons in a channel region between a source region and a drain region of the SONOS memory cells and for letting the electrons tunnel directly into the nitride layer. A preferred voltage bias to be used in the electrical erase step has an amount of 10 V. This voltage bias is preferably distributed over source and control gate terminals by applying a voltage of 3 V to the control gate terminal and a voltage of −7 V to the source terminal for a time span of between 0.1 second and 5 seconds. Preferably also to the well. This way, high-voltage transistors are not required even during an electrical erase procedure. Preferably, a voltage of the same amount and sign as applied to the source terminal is also applied to the drain terminal of the SONOS memory cells and to doped wells of the SONOS memory cells during the erasing step.

According to a third aspect of the invention, a programming device for programming a SONOS memory device according to the first aspect of the invention or one of its embodiments is provided. The programming device comprises an erasing unit, which has:
a bit line float output port, which is configured for connection to a bit-line float bond pad of the SONOS memory device,
a common-source output port, which is configured for connection to the common-source bond pad of the SONOS memory device, and
a control gate output port.

The erasing unit is configured to generate and provide a first erase voltage component at the bit line float output port and at the common-source output port, and to generate and provide a second erase voltage component at the control gate output port. The first and second erase voltage components add to an erase voltage bias suitable for creating electrons in a channel region between a source region and a drain region of the SONOS memory cells and for letting created electrons tunnel directly into the nitride layer.

The programming device is useful for electrically erasing a SONOS memory device, which has been described hereinabove. The programming device thus performs the step of providing the memory device in an erased state as described in the context of previous embodiments. The programming device thus enables multi-time programming of SONOS memory devices.

In a preferred embodiment of the programming device the control gate output port is formed by a power supply output port, which is configured for connection to a power input bond pad of the SONOS memory device.

Note that the term “bond pad” as used in the present application is to be understood in a functional way as a suitable electrical interface, which can be used for applying the voltages mentioned. Such an electrical interface can for instance also be formed by contact pins.

In the following, the invention will be further explained and preferred embodiments will be presented with reference to the enclosed Figures. In the Figures:

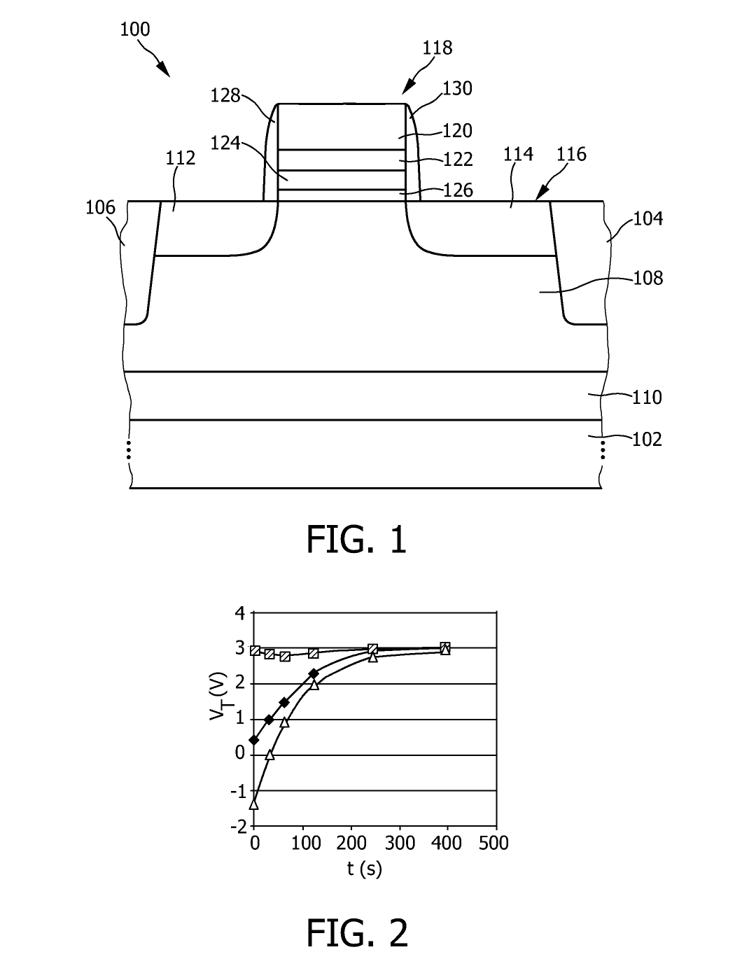

FIG. 1 shows a schematic cross sectional view of a SONOS memory cell according to an embodiment of the invention.

FIG. 2 shows a diagram that shows the dependence of the threshold voltage V_{T} of a NMOS SONOS memory cell on the duration of exposure to ultraviolet illumination.

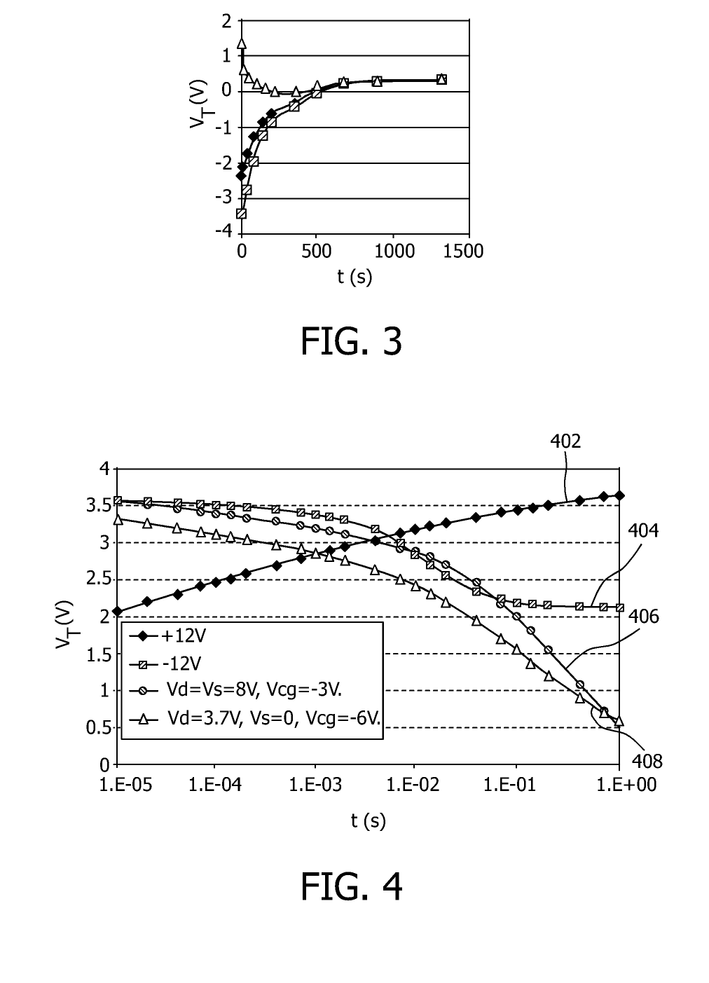

FIG. 3 shows a diagram that shows the dependence of the threshold voltage V_{T} of a PMOS SONOS memory cell on the duration of exposure to ultraviolet illumination.

FIG. 4 shows a number of program and erase curves for a single NMOS SONOS memory cell.

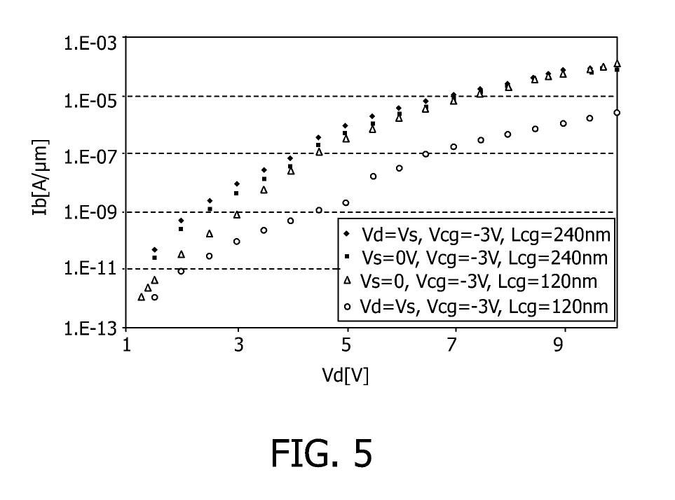

FIG. 5 shows simulations of a gate-assisted band-to-band tunneling hole current under different bias conditions for two SONOS memory cells with different channel lengths.

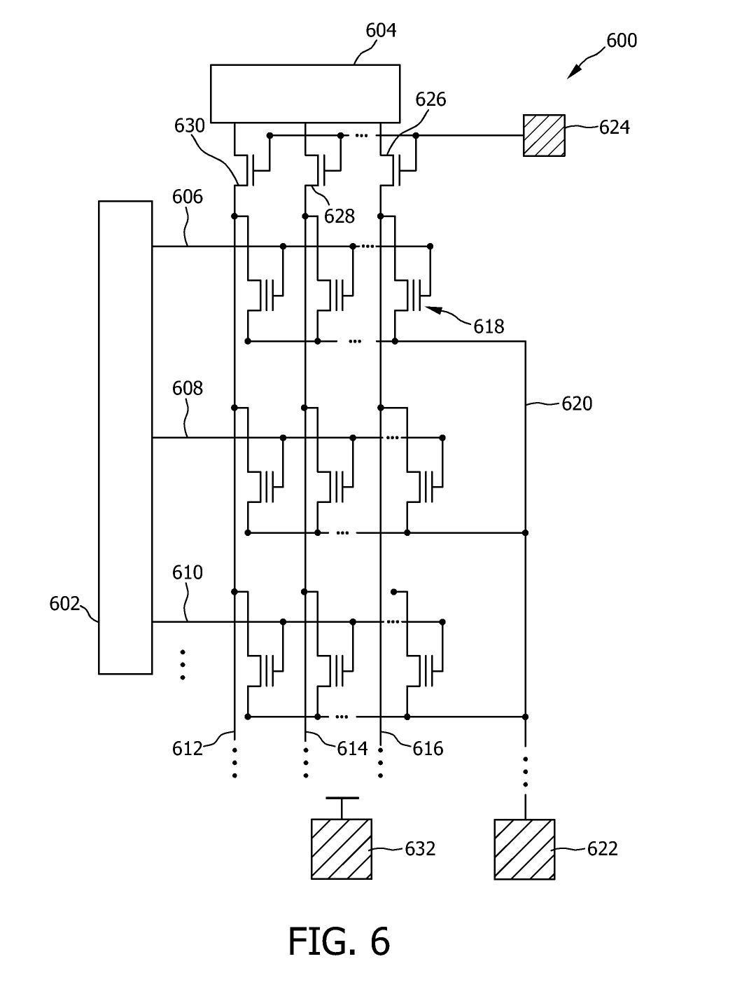

FIG. 6 shows a schematic circuit diagram of a SONOS memory array according to one embodiment of the present invention.

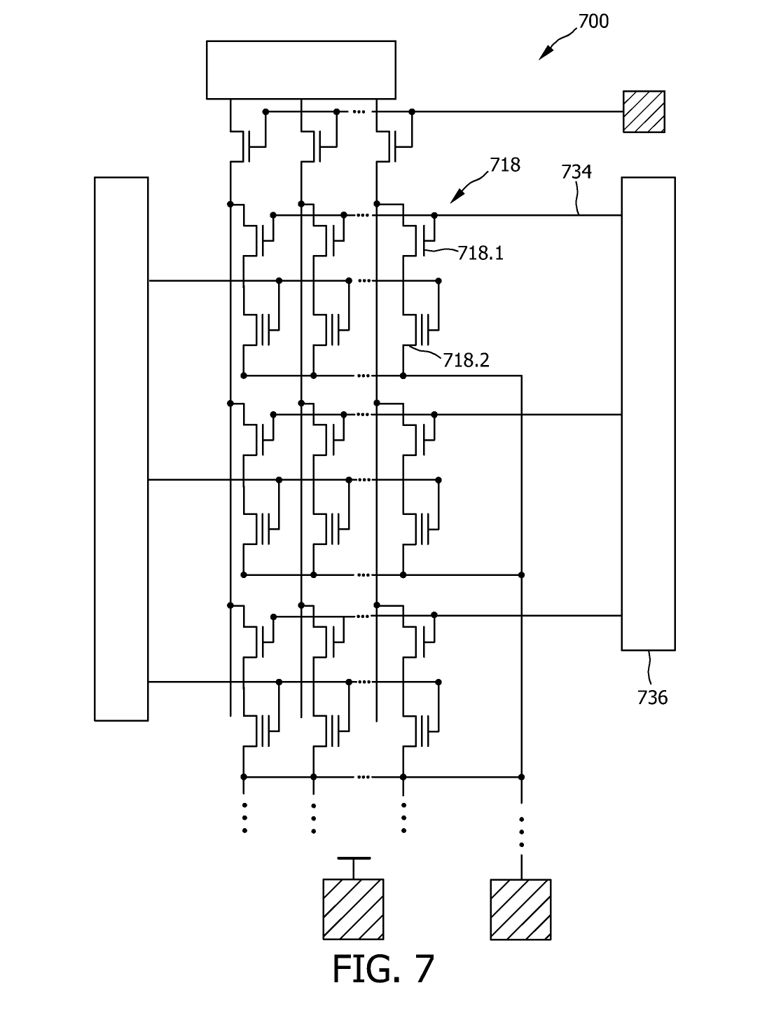

FIG. 7 shows a schematic circuit diagram of an alternative memory array configuration.

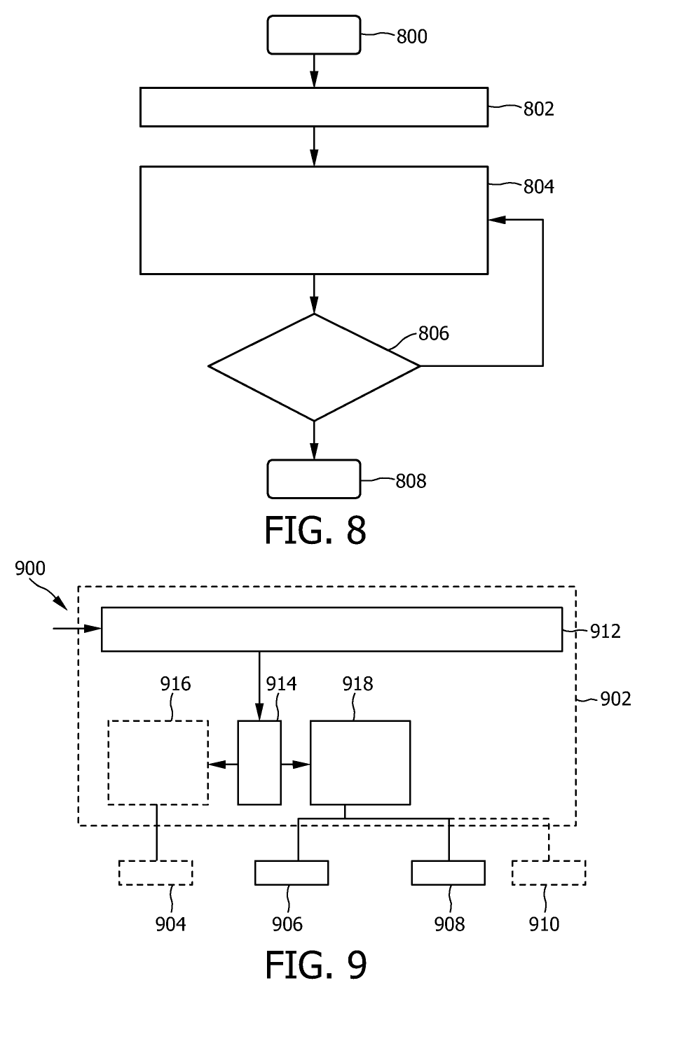

FIG. 8 shows a flow diagram of an embodiment of a method of operating a SONOS memory device.

FIG. 9 shows a schematic block diagram of a programming device for programming a SONOS memory device according to an embodiment of the invention.

FIG. 1 shows a schematic cross sectional view of a SONOS memory cell according to an embodiment of the invention. The SONOS memory cell 100 is shown in a simplified schematic manner. All structural elements related to contacting the memory cells are omitted in FIG. 1 for simplicity. However, the skilled person is well aware of such additional.

The memory cell is manufactured on a silicon substrate 102 in an active area 108, which is laterally confined by field isolation regions 104 and 106. For the present example it is assumed without restriction that the active area 108 between the field isolation regions 104 and 106 is a p-doped well, which is isolated by a buried n-well 110 underneath. A source region 112 and a drain region 114 form shallow doped areas near a surface 116 of the substrate.

A SONOS layer stack 118 is formed on the substrate surface 116 and comprises, from top to bottom, a polysilicon layer 120, a blocking oxide layer 122, a silicon nitride layer 124, and a bottom oxide layer 126. The silicon nitride layer is herein also referred to in short as a nitride layer. Lateral spacers 128 and 130 are made of an isolating material.

In a preferred embodiment, which enhances data retention, and which is particularly suited to the HHI programming mechanism employed, the bottom oxide layer has a thickness of 5 to 7 nm. The bottom oxide layer 126, as well as the blocking oxide layer 122 are made of silicon dioxide SiO₂. However, other isolating materials may be suitable as well, as is known in the art.

Details of the operation of the memory cell 100 will be described in the context of the following Figures.

In the following, erase transients of NMOS and PMOS SONOS memory cells will be described with reference to FIGS. 2 and 3. FIG. 2 shows the dependence of the threshold voltage V_{T} of an NMOS SONOS memory cell on the duration of exposure to UV illumination. The diagram of FIG. 2 shows three different UV erase transients for an NMOS SONOS memory cell. FIG. 3 shows the dependence of the threshold voltage V_{T} of a PMOS SONOS memory cell on the duration of exposure to UV illumination.

The following symbols are used with the same meaning in both FIGS. 2 and 3: filled diamonds indicate UV erase transients of a “virgin” SONOS memory cell, which is erased during manufacturing for the first time. Open triangles show UV erase transients for a SONOS memory cell, which has previously been programmed. Filled squares represent an UV erase transient for a SONOS memory cell, which has previously been erased.

As can clearly be seen from the UV erase transients of FIGS. 2 and 3, the state of equilibrium of a SONOS memory cell that is reached after UV illumination is a state that is characterized by a high threshold voltage V_{T} of the MOSFET device, which is formed by the memory cell (cf FIG. 1). This holds for both NMOS and PMOS SONOS memory cells. From FIG. 2, the threshold voltage V_{T} reached after UV erasure of a NMOS SONOS memory cell is approximately 3 V. From FIG. 3, the state of equilibrium reached after UV erasure in a PMOS SONOS memory cell is 0.5 V.

According to a current interpretation of this effect, UV illumination seems to cause a filling of a substantial faction of trap sites in the silicon nitride layer 124 (cf. FIG. 1) with electrons.

FIG. 4 shows program and erase transients for a NMOS SONOS memory cell. As in FIGS. 2 and 3, the threshold voltage is plotted against programming or erasure time. The transients shown are indicative of different embodiments of a method of operating a memory cell according to the present invention, with one exception, which will be clearly pointed out during the following further description of FIG. 4.

The transients shown in FIG. 4 were taken from an NMOS SONOS memory cell having a transistor with a channel length of 0.23 μm, a bottom oxide thickness of 2.4 nm and a width parameter W of 0.48 μm. W means the width of the active area 108 in FIG. 1 in the third dimension perpendicular to the plane of the cross section depicted in FIG. 1 The transients were measured using a read current of 10⁻⁵ A and a drain-source bias V_{ds} of 0.5 V.

In FIG. 4, an electrical erasure transient 402 is represented by solid diamonds. The electrical erasure transient 402 was recorded using a gate voltage of +12 V. As can clearly be seen, an application of this gate voltage results in a shift of the threshold voltage V_{T} to higher values in a way corresponding to that shown in FIG. 1 for a different NMOS transistor under exposure to UV illumination. Further details of the electrical erase procedure and alternative embodiments of performing the electrical erase procedure will be described further below in the context of FIG. 6 to 9.

A transient 404 represented by full squares does not form an embodiment of the present invention and forms the above-mentioned exception. This transient was recorded under application of a voltage of −12 V to the gate terminal of the NMOS SONOS memory cell, corresponding to the polysilicon layer 120 of the device shown in FIG. 1. Under these conditions, a direct tunneling mechanism occurs, in which holes of the active region 108 near the substrate surface 116 tunnel directly into the nitride layer 124, without a preceding BTBT process in the substrate. As can be seen from the development of the transient for this case, a saturation is observed towards the end of the programming period between 0.1 s and 1 s. This transient therefore shows that direct tunneling is not suitable for programming a SONOS memory cell. The window of V_{T} values between the erased (3.5 V) and the programmed states (2.1 V) is rather small and makes reading the memory device difficult. Furthermore, the programming voltage of −12 V is rather large and requires dedicated HV transistors.

Next, suitable embodiments of programming will be described with reference to the remaining transients in FIG. 4. Two further transients 406 and 408 are shown that start from a high-V_{T} state. These transients thus correspond to programming steps performed in a method of operating a SONOS memory cell.

A first embodiment of a programming step is thus represented by a transient 406 shown by full circles. This transient was recorded under application of a drain voltage V_{d} of +8 V, a source voltage Vₛ of +8 V and a gate voltage V_{eg} of −3 V. During the programming time of 1 s, the threshold voltage V_{T} is switched from its original erased state (3.5 V) to a low-V_{T} state of 0.5 V.

A further suitable embodiment is represented by transient 408, in which the drain voltage V_{d} amounts to 3.7 V, the source voltage Vₛ amounts to 0 V, and the gate voltage V_{eg} amounts to −6 V. With these values, the memory cell formed by the SONOS transistor is switched from a high-V_{T} state at 3.3 V to a low-V_{T} state at 0.5 V within 1 s. The latter embodiment has the advantage of requiring smaller voltage magnitudes than those used for transient 406, which smaller voltage magnitudes can be provided by conventional I/O transistors, thus rendering the use of dedicated high-voltage transistors for providing the suitable programming voltages unnecessary.

FIG. 5 shows simulations of a gate-assisted band-to-band tunneling hole current under different bias conditions for two SONOS memory cells with different channel lengths. The diagram shows the dependence of a gate-assisted band-to-band tunneling hole current on the drain voltage V_{d} for a first device with a channel length of 240 nm (filled diamonds and filled squares) and for a second device with a channel length of 120 nm (open triangles and open circles). Two cases are plotted for each device: A first case, in which the source voltage Vₛ equals the drain voltage V_{d}, and a second case, in which the source voltage Vₛ is 0 V. The gate voltage V_{eg} is −3 V in all simulations plotted. It should be noted that the calculated current density in FIG. 5 represents the total hole current density and that only a small fraction of the generated holes is in fact injected into the nitride layer of a SONOS memory cell.

It can clearly be observed from the simulations shown in FIG. 5 that in longer devices the hole generation is more efficient if the voltage is applied to both the source and the drain terminals and thus holes are generated at the source as well as at the drain. Shorter devices exhibit a more efficient hole generation if only the drain is used for hole generation. It should be kept in mind, however, that in many array configurations, such as for instance a 1 T NOR configuration, only the drain junction can be biased selectively for programming. Therefore, applying the same voltage to both source and drain junctions is restricted to suitable memory array configurations.

FIG. 6 shows a schematic circuit diagram of a SONOS memory array according to one embodiment of the present invention. The memory device 600 of FIG. 6 is organized according to a 1 T OR architecture, which is well known per se. The SONOS memory device 600 has a word-line driver 602 and a bit-line driver 604. Three exemplary word lines 606, 608, and 610, and three exemplary bit lines 612, 614, and 616 are shown. SONOS memory cells are indicated by transistor symbols, in which the nitride layer is symbolized by an additional intermediate line. Three exemplary memory cells are drawn in each word line and in each bit line.

The electrical connections of the memory cells are described with reference to an exemplary SONOS memory cell 618. The control gate of SONOS memory cell 618 is connected to the word-line driver via word line 606. The drain terminal of SONOS memory cell 618 is connected to bit-line driver 604 via bit line 616. The source terminal of the SONOS memory cell 618 is connected to a common source line 620 and to a common source bond pad 622. As can clearly be seen from FIG. 6 all source terminals of the memory cells share the connection to the common source bond pad 622.

The memory device 600 further comprises a bit-line float bond pad 624, which is connected with bit-line float transistors 626, 628, and 630 in parallel. Each bit-line float transistor is connected with its control gate to the bit-line float bond pad. The drain of the bit-line float transistors is connected to the bit-line driver 604 via the respective bit line 612, 614 or 616. The source terminal of the bit-line float transistors is connected with the drain side of the memory cells along the respective bit line.

Furthermore, a well bond pad 632 is provided, which is connected with the p-wells of the memory cells, which have a structure corresponding to that shown in FIG. 1.

For an electrical erase operation of the SONOS memory device 600 a gate voltage of +3V is applied to the control gates of all memory cells by word-line driver 602. For simplicity, control circuitry instructing the word-line driver to generate this voltage is not shown in FIG. 6. The voltage mentioned of +3V is to be considered to be an example and may have to be varied depending on the device structure. However, it is advantageous to keep the gate voltage within a range that can be handled by I/O transistors during a programming time of between 0.1 s and 5 s.

During the electrical erase operation, the bit-line driver keeps its output voltage at 0 V. In synchronism with the application of the gate voltage mentioned, a voltage of approximately −7 V is applied to the bit-line float bond pad 624, the common source bond pad 622 and the well bond pad 632. Again, the value of −7 V is to be considered to be an example, actual values may vary. This voltage is applied to the bond pads by an external voltage source, such as provided by a programming device, which will be described with reference to FIG. 9 below.

The aim of the electrical erasure procedure just described is to have only a limited voltage on the control gates and to create the remaining component of the required erase voltage by negatively biasing the common source and the well, which in the present case is advantageously an isolated p-well with a buried n-well underneath, as shown in FIG. 1. After this erasure procedure, the common source bond pad 622 and the well bond pad 632 can be connected to ground or, if necessary for other functions such as reading or programming, to another bond pad. Of course, instead of bond pads other contact elements can be used, such as pins etc. As a result, an effective erase bias of approximately 10 V is applied during the erase step without having to rely on dedicated high-voltage transistors.

Since the memory transistors (618) are in inversion (conduction) during the erase procedure (the gate-source voltage amounting to approximately 10 V) the drain should be at the same bias as the source in order to prevent excessive channel currents. To this purpose, the bit lines are left floating by means of the bit-line float transistors 626 to 630. The bit-line float transistors are selected to isolate and withstand a voltage amount of approximately 7 V in the present example. Since this bias situation only occurs for a very limited time of a few seconds, the bit-line float transistors can be made with I/O transistors or reference transistors.

As the number of bit-line float transistors is not large, they can be made relatively long for optimum isolation of the applied voltage and wide in order to have a minimum effect on the read current without a severe area penalty. During read and write operations, the bit-line float transistors are opened by applying the power supply potential V_{DD} to the bit-line float bond pad.

FIG. 7 shows a schematic circuit diagram of an alternative memory array configuration. The memory device 700 of FIG. 7 differs from that in FIG. 6 by implying 2 T memory cells instead of 1 T memory cells. The 2 T architecture is well known in the art and differs from the 1 T architecture in an additional select transistor connected in series to the memory transistor of each memory cell. As an example, a memory cell 718 contains a select transistor 718.1, which has a source terminal connected with the drain terminal of memory transistor 718.2. The gate terminal of select transistor 718.1 is connected to a select line 734, and to a select line driver 736.

Further structural details and the operational principles correspond to those described in the context of the memory device 600 of FIG. 6.

FIG. 8 shows a flow chart of an embodiment of a method of operating a SONOS memory device. The method is started with a step 800. At a step 802, the SONOS memory device is provided in an erased state. This means that all memory cells are switched into a high-V_{T} state.

In one embodiment, step 802 includes exposing the memory cells to UV illumination for a suitable time span. From FIGS. 2 and 3, suitable time spans are between 5 and 20 min. This erase option is particularly suitable during manufacture of the device. However, after packaging the memory device, UV illumination does not reach the memory cells. In this case, the following alternative erase method is advantageous, as has been described with reference to FIG. 6. The use of an electrical erase method has the advantage of opening the possibility to program the memory device a plurality of times thus rendering the memory device of the invention a multi-time programmable memory device.

In step 804, programming of a selected memory cell is performed by applying a suitable gate voltage and a suitable drain voltage through a word-line driver and a bit-line driver of the memory device. Several examples of suitable programming conditions have been presented in the foregoing description. The essence is that a hot hole injection mechanism is used for the programming of the memory cells. After performing the programming step for a selected memory cell, it is checked in step 806 whether a further memory cell has to be programmed. If so, the method brunches back to step 804 to program a next memory cell. If not, the method ends with step 808.

It is obvious that variations to the above method are possible. For instance, different memory cells can be programmed in parallel as long as unintentional programming of other memory cells can be avoided.

FIG. 9 shows a schematic block diagram of a programming device 900 for programming a SONOS memory device according to an embodiment of the invention. The programming device is useful for erasing a SONOS memory device, which has been described hereinabove. The programming device thus performs the step of providing the memory device in an erased state as described in the context of previous embodiments. The programming device contains an erasing unit 902, which receives external control signals and comprises a bit-line float output port 906, a common-source output port 908 and a control gate output port 904. Optionally, a well output port 910 can also be provided. The erasing unit 902 comprises a control unit 912, which controls operation of a timing unit 914. The timing unit 914 is connected to a control-gate voltage source 916 and a common voltage source 918. The control-gate voltage source 916 is configured to provide an output voltage of approximately 3 V, which is to be understood as an exemplary value. The common voltage source 918 is configured to provide a voltage of approximately −7 V. Both voltage sources operate in dependence on timing signals received from the timing unit 914. That is, timing unit 914 controls the points in time, when the voltage sources 916 and 918 are turned on and turned off.

In an alternative embodiment, the erasing using does not have a control gate output, and a corresponding control gate voltage source can be omitted. The programming device of this embodiment can be used in a context where the memory device is powered by a power supply, so that the voltage that has to be applied to the control gates is provided through the power supply.

It is understood that the output ports of the programming device are arranged to contact the corresponding bond pads or pins provided at a memory device to be programmed.

In a further embodiment, the programming device 900 further comprises programming circuitry, which can be used for programming an erased memory device in a bit selective manner as described with reference to the previous embodiments.

In summary, the present invention provides a SONOS memory device and a method of operating same, which allows a low-voltage programming by using a hot hole injection mechanism. Erasure of the memory cells can be performed by UV illumination or an electrical erasure procedure making use of direct tunneling mechanism. The memory cells can be equipped with a thick bottom oxide layer that enhances data retention properties. Furthermore, by using an electrical erase mechanism, a multi-time-programmable memory device is provided.

When interpreting the present description and its associated claims, expressions such as “comprise”, “include”, “incorporate”, “contain”, “is”, and “have” are to be construed in a non-exclusive manner, namely construed to allow other items or components, which are not explicitly defined, also to be present. Reference to the singular is also to be construed to be a reference to the plural and vice versa.

Furthermore, the invention may also be embodied with fewer components than provided in the embodiments described here, wherein one component carries out multiple functions. Just as well the invention may be embodied using more elements than depicted in the Figures, wherein functions carried out by one component in the embodiment provided are distributed over multiple components.

A person skilled in the art will readily appreciate that various parameters disclosed in the description may be modified and that various embodiments disclosed and/or claimed may be combined without departing from the scope of the invention.

It is stipulated that the reference signs in the claims do not limit the scope of the claims, but are merely inserted to enhance the legibility of the claims.

1. A method of operating a memory device comprising Silicon-Oxide-Nitride-Oxide-Silicon memory cells, the method comprising a step of programming a selected SONOS memory cell, which step includes:
providing the SONOS memory device in an erased state, in which the selected SONOS memory cell is in a high-V_{T} state; and
applying a predetermined positive drain voltage to a drain terminal of the selected SONOS memory cell and a predetermined negative gate voltage to a control gate terminal of the selected SONOS memory cell, the drain voltage and the gate voltage being suitable for creating hot holes at a drain terminal of the selected SONOS memory cell in a gate-assisted band-to-band-tunneling process and for injecting the hot holes into a nitride layer of the selected SONOS memory cell, thus switching from the high-V_{T} state to a low-V_{T} state.

2. The method of claim 1, wherein the step of programming the selected SONOS memory cell further includes applying a predetermined positive source voltage to a source terminal of the SONOS memory cell, the source voltage being suitable for creating hot holes also on the source side of the SONOS memory cell.

3. The method of claim 1, wherein the step of programming the selected SONOS memory cell comprises applying a drain voltage between 3 V and 7 V to the drain terminal and a gate voltage between −2 V and −6V to the control gate terminal.

4. The method of claim 1, wherein the step of programming the selected SONOS memory cell comprises applying the predetermined positive drain voltage and the predetermined negative gate voltage of the selected SONOS memory cell for a time span of between 0.1 second and 5 seconds.

5. The method of claim 1, wherein the step of providing the SONOS memory device in an erased state comprises electrically erasing the SONOS memory cells by applying an erase voltage bias across their control gates and their source terminals, the erase voltage bias being suitable for creating electrons in a channel region between a source region and a drain region of the SONOS memory cells and for letting the electrons tunnel directly into the nitride layer.

6. The method of claim 5, wherein the erase voltage bias is applied by applying a voltage of 3 V to the control gate terminal and a voltage of −7 V to the source terminal for a time span of between 0.1 second and 5 seconds.

7. A memory device, hereinafter Silicon-Oxide-Nitride-Oxide-Silicon (SONOS) memory device, comprising:
SONOS memory cells having a control gate terminal connected to a SONOS layer stack with a nitride layer, and further having a source terminal and a drain terminal; and
a programming unit, which is connected to the drain terminal and to the control gate terminal and which is configured to apply a predetermined positive drain voltage to the drain terminal of the selected SONOS memory cell and a predetermined negative gate voltage to the control gate terminal of the selected SONOS memory cell each upon receiving a programming request addressed to a selected SONOS memory cell,
the drain voltage and the gate voltage being suitable for creating hot holes at a drain side of the selected SONOS memory cell in a gate-assisted band-to-band-tunneling process and for injecting the hot holes into the nitride layer of the selected SONOS memory cell, thus switching the selected SONOS memory cell from a high-V_{T} state to a low-V_{T} state.

8. The SONOS memory device of claim 7, wherein the programming unit comprises input/output transistors for providing the drain voltage and the gate voltage, respectively, to the SONOS memory cells, the input/output transistors being connected to the SONOS memory cells and nominally configured to provide a maximum output voltage of approximately 2.5 V.

9. The SONOS memory device of claim 7, wherein the SONOS layer stack has a bottom oxide layer adjacent to a substrate on one side and to the nitride layer on another side, and wherein the thickness of the bottom oxide layer is between 5 and 7 nm.

10. The SONOS memory device of claim 7, comprising an array of SONOS memory cells, which are connected according to a NOR architecture.

11. The SONOS memory device of claim 10, wherein the programming unit comprises:
a bit line driver, which is connected in parallel to the drain terminals of respective SONOS memory cells arranged along a respective bit line; and
a word line driver, which is connected in parallel to the control gate terminals of respective SONOS memory cells arranged along a respective word line;
wherein the bit line driver is configured to apply the predetermined positive drain voltage to the connected drain terminals of a selected bit line, and the word line driver is configured to apply the predetermined negative gate voltage to the control gate terminals of a selected word line, each upon receiving a programming request addressed to the selected SONOS memory cell.

12. The SONOS memory device of claim 11, further comprising respective bit line float transistors connected in series between the bit line driver and drain terminals of SONOS memory cells, the SONOS memory cells being connected to a respective bit line downstream of the bit line driver and the respective bit line float transistor, wherein a gate terminal of a respective bit line float transistor is connected to a bit-line float bond pad common to all bit line float transistors.

13. The SONOS memory device of claim 7, further comprising a well bond pad, which is connected to a common doped well (108) of the SONOS memory cells in the substrate.

14. The SONOS memory device of claim 7, further comprising a buried isolation well of opposite conductivity type to the doped well and arranged underneath the doped well.

15. A programming device for programming a Silicon-Oxide-Nitride-Oxide-Silicon (SONOS) memory device according to claim 7, comprising an erasing unit, which has
a bit line float output port, which is configured for connection to a bit-line float bond pad of the SONOS memory device,
a common-source output port, which is configured for connection to the common-source bond pad of the SONOS memory device,
a control gate output port,
wherein the erasing unit is configured to generate and provide a first erase voltage component at the bit line float output port and at the common-source output port, and to generate and provide a second erase voltage component at the control gate output port, wherein the first and second erase voltage components add to an erase voltage bias suitable for creating electrons in a channel region between a source region and a drain region of the SONOS memory cells and for letting created electrons tunnel directly into a nitride layer of the SONOS memory cells.
